(19) United States
(12) Patent Application Publication
(10) Pub. No.: US 2026/0282964 A1
(43) Pub. Date: Sep. 17, 2026

(54) PACKAGE COMPRISING A SUBSTRATE THAT INCLUDES A STACK OF INTERCONNECTS

(71) Applicant: QUALCOMM Incorporated, San Diego, CA (US)

(72) Inventors: Aniket PATIL, San Diego, CA (US); Joan Rey Villarba BUOT, Escondido, CA (US); Yangyang SUN, San Diego, CA (US)

(21) Appl. No.: 19/080,714

(22) Filed: Mar. 14, 2025

(51) Int. Cl. H01L 23/498

(52) U.S. Cl. CPC H10W 70/65; H10W 90/701

(57) ABSTRACT

A package comprising a substrate comprising: at least one dielectric layer; and a plurality of interconnects comprising a stack of interconnects that include a first pad interconnect; a first via interconnect coupled to the first pad interconnect; a second pad interconnect coupled to the first via interconnect; at least two second via interconnect coupled to the second pad interconnect; and a third pad interconnect coupled to the at least two second via interconnect; and an integrated device coupled to the stack of interconnects.

### FIELD

Various features relate to packages and substrates.

### BACKGROUND

A package may include a substrate and integrated devices. These components are coupled together to provide a package that may perform various electrical functions. There is an ongoing need to provide better performing packages, including more robust and/or reliable packages. Moreover, there is also an ongoing need to reduce and/or minimize the overall size of the packages.

### SUMMARY

Various features relate to packages and substrates.

One example provides a package comprising a substrate comprising: at least one dielectric layer; and a plurality of interconnects comprising a stack of interconnects that include a first pad interconnect; a first via interconnect coupled to the first pad interconnect; a second pad interconnect coupled to the first via interconnect; at least two second via interconnect coupled to the second pad interconnect; and a third pad interconnect coupled to the at least two second via interconnect; and an integrated device coupled to the stack of interconnects.

Another example provides a package comprising a substrate comprising at least one dielectric layer; and a plurality of interconnects comprising: a plurality of a stack of interconnects comprising a first plurality of via interconnects, wherein vias interconnects from the first plurality of via interconnects comprise a first height; and a second plurality of via interconnects, wherein via interconnects from the second plurality of via interconnects comprise a second height that is different from the first height; and an integrated device coupled to the plurality of a stack of interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes an integrated device and a substrate comprising stacks of interconnects.

FIG. 2 illustrates an exemplary cross sectional profile view of a package that includes an integrated device and a substrate comprising stacks of interconnects.

FIG. 3 illustrates an exemplary view of a stack of interconnects.

FIG. 4 illustrates an exemplary cross sectional profile view of a package that includes an integrated device and a substrate comprising stacks of interconnects.

FIGS. 5A-5H illustrate an exemplary sequence for fabricating a substrate that includes stacks of interconnects.

FIG. 6 illustrates an exemplary flow diagram of a method for fabricating a substrate that includes stacks of interconnects.

FIG. 7 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate comprising: at least one dielectric layer; and a plurality of interconnects comprising a stack of interconnects that include a first pad interconnect; a first via interconnect coupled to the first pad interconnect; a second pad interconnect coupled to the first via interconnect; at least two second via interconnect coupled to the second pad interconnect; and a third pad interconnect coupled to the at least two second via interconnect; and an integrated device coupled to the stack of interconnects. The plurality of a stack of interconnects may help the package be more resistant to stress and/or delamination during a bumping process of an integrated device to a substrate.

### Exemplary Package Comprising a Substrate With Stacks of Interconnects

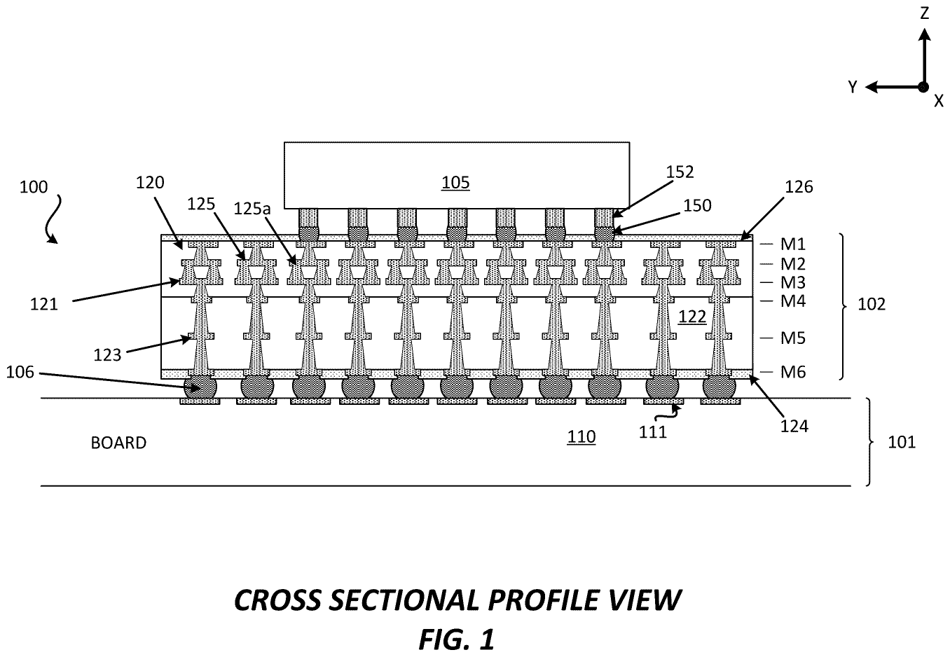

FIG. 1 illustrates a cross sectional profile view of a package 100 that includes an integrated device and a substrate that may include a stack of interconnects. The package 100 is coupled to a board 101 through a plurality of solder interconnects 106. The board 101 includes at least one board dielectric layer 110 and a plurality of board interconnects 111. The board 101 may include a printed circuit board (PCB).

The package 100 may include a substrate 102 and an integrated device 105. The substrate 102 may be a coreless substrate. The substrate 102 may include at least one dielectric layer 120, at least one dielectric layer 122, a plurality of interconnects 121, a plurality of interconnects 123, a solder resist layer 124 and a solder resist layer 126. The plurality of interconnects 121 may be coupled to the plurality of interconnects 123. The at least one dielectric layer 120 may be coupled to the at least one dielectric layer 122. In some implementations, the at least one dielectric layer 120 and the at least one dielectric layer 122 may be part of the same dielectric layer. The solder resist layer 126 may be coupled to the at least one dielectric layer 120. The solder resist layer 126 may be coupled to the at least one dielectric layer 122.

The plurality of interconnects 121 may include a plurality of a stack of interconnects 125. The plurality of a stack of interconnects 125 may include a stack of interconnects 125a. The stack of interconnects 125a may be an interconnect structure. The stack of interconnects 125a may include a first pad interconnect, a first via interconnect coupled to the first pad interconnect, a second pad interconnect coupled to the first via interconnect, at least one second via interconnect coupled to the second pad interconnect, a third pad interconnect coupled to the at least one second via interconnect, a third via interconnect coupled to the third pad interconnect. The first via interconnect may be horizontally offset to the at least one second via interconnect. The at least one second via interconnect may include two or more second via interconnects that are horizontally offset to the first via interconnect. The stack of interconnects 125a may also include a fourth pad interconnect coupled to the third via interconnect. The third via interconnect may be horizontally offset to the at least one second via interconnect. The at least one second via interconnect may include two or more second via interconnects that are horizontally offset to the third via interconnect. The first pad interconnect may be a landing pad interconnect. A landing pad interconnect may be a pad interconnect that is coupled to and touching a solder interconnect and/or a solder bump interconnect.

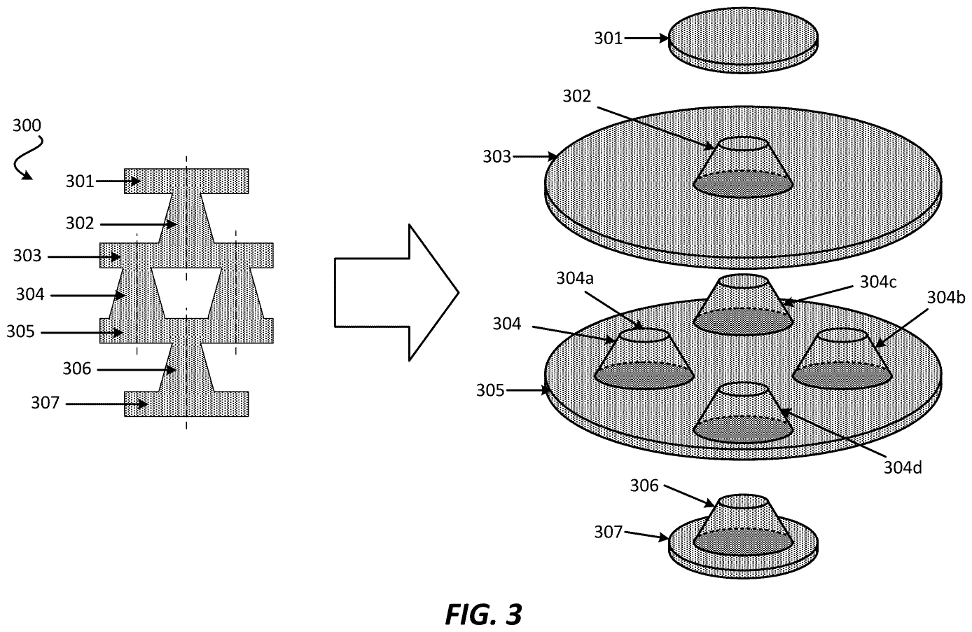

The horizontal offset of the at least one second via interconnect to the first via interconnect and/or the third via interconnect, may help the package absorb stress, reduce delamination and/or reduce crack propagation in the package. Moreover, the stacks of interconnects may improve the power distribution network performance of the package. In addition, the use of stacks of interconnects may allow for more aggressive pitch between interconnects, and thus higher density interconnects. A more detailed example of a stack of interconnects is further illustrated and/or described below in at least FIG. 3.

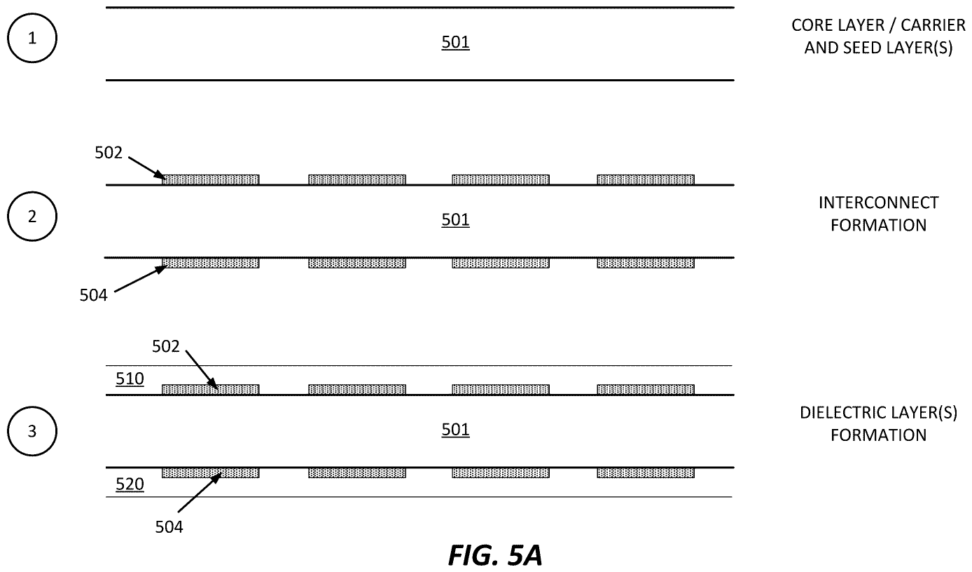

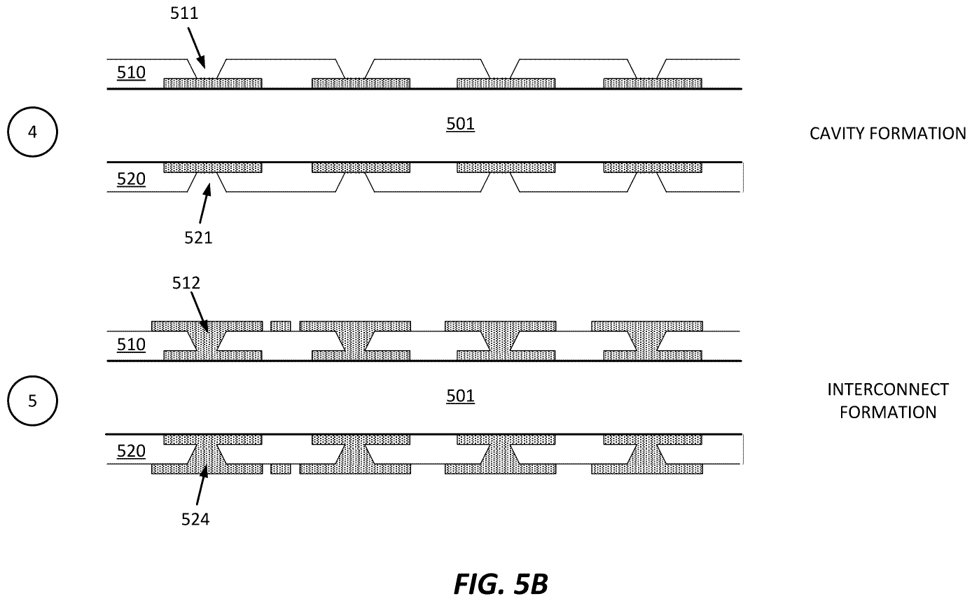

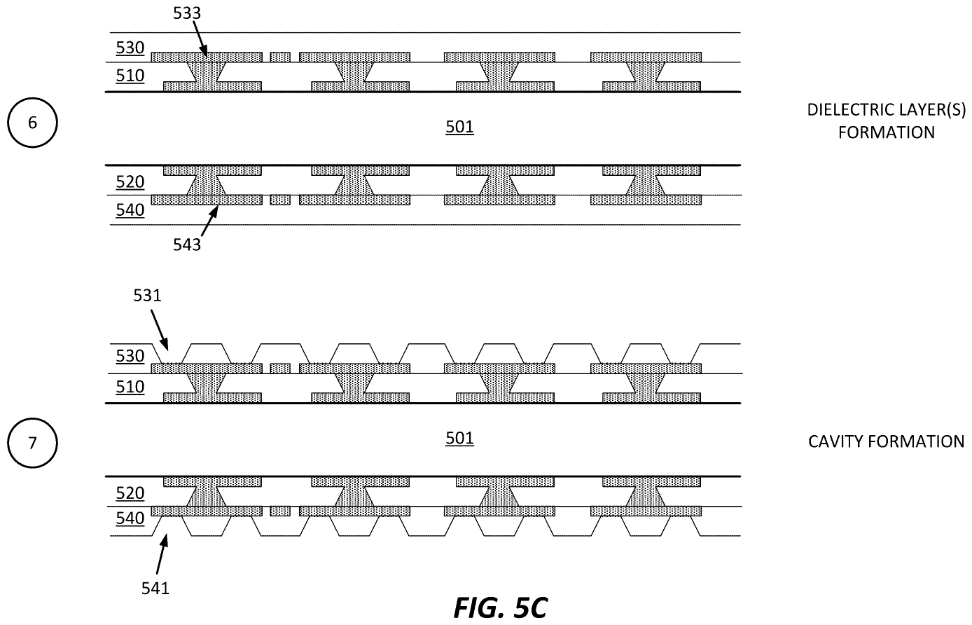

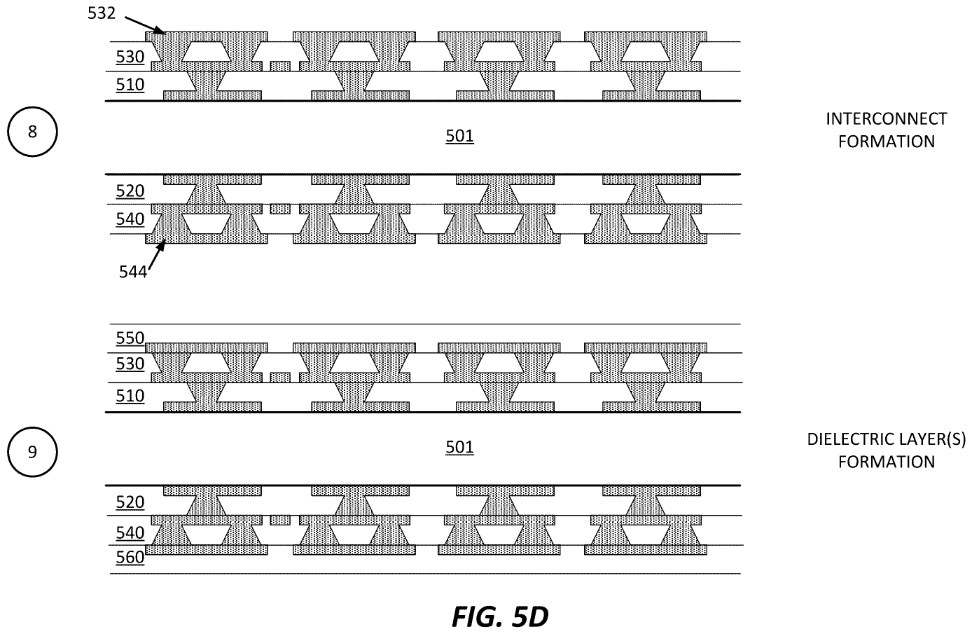

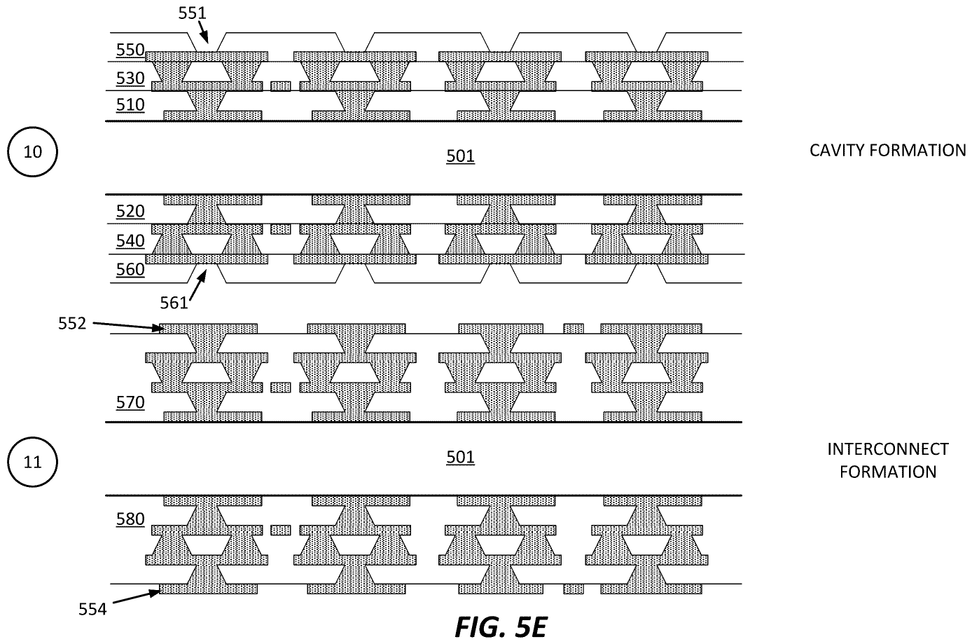

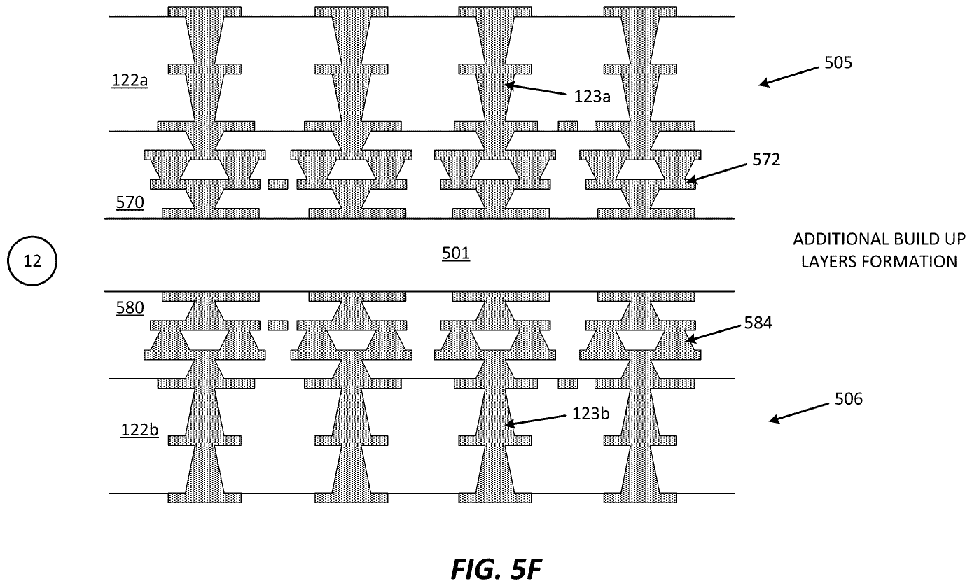

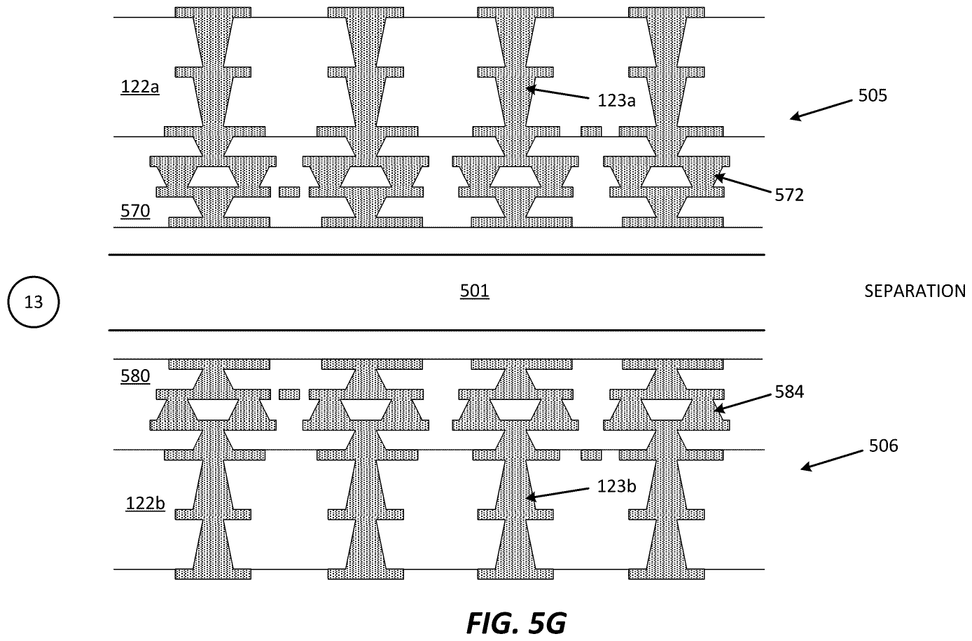

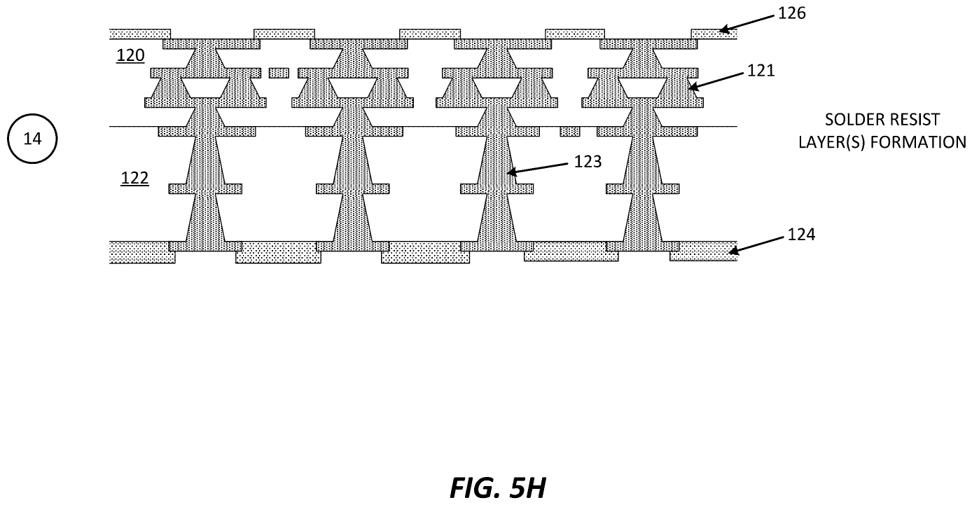

In some implementations, the plurality of interconnects 121 include via interconnects with a first height and the plurality of interconnects 123 include via interconnects with a second height that is different from the first height. In some implementations, the second height of the via interconnects from the plurality of interconnects 123 may be greater than the first height of the via interconnects from the plurality of interconnects 121. FIGS. 5A-5H illustrate an example of a process for fabricating a substrate that includes stacks of interconnects.

The integrated device 105 is coupled to the substrate 102 through a plurality of pillar interconnects 152 and/or a plurality of solder interconnects 150. The plurality of pillar interconnects 152 and/or the plurality of solder interconnects 150 may be coupled to the plurality of a stack of interconnects 125. The plurality of pillar interconnects 152 and/or the plurality of solder interconnects 150 may be coupled to and touch landing pad interconnects of the plurality of a stack of interconnects 125.

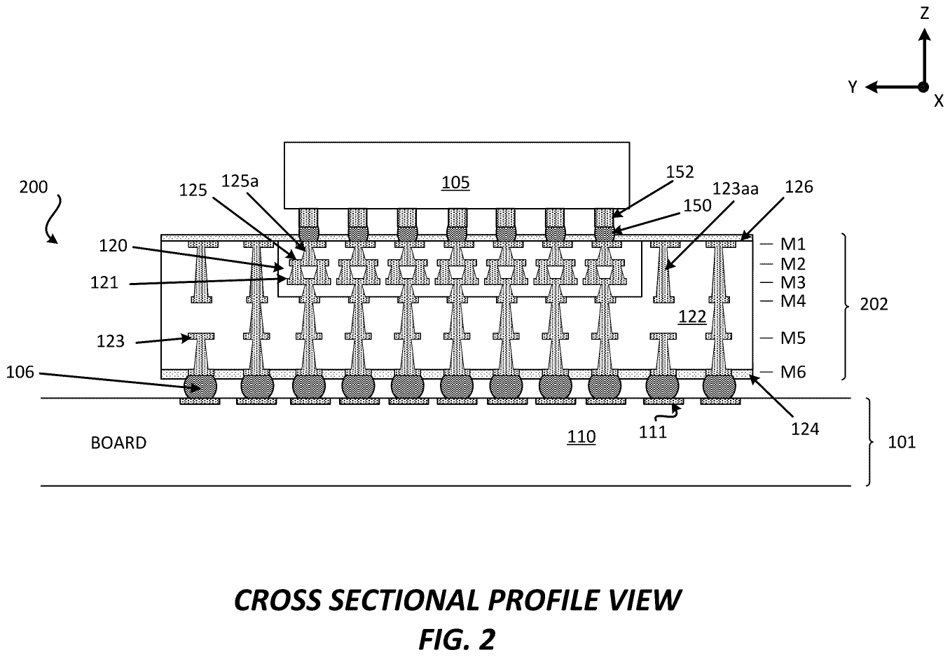

FIG. 1 illustrates an example of a substrate where a portion of the substrate that includes the plurality of a stack of interconnects 125 extend along the entire length and/or width of the substrate 102. FIG. 2 illustrates an example of a substrate where a portion of the substrate that includes the plurality of a stack of interconnects 125 extends for only part of the length and/or only part of the width of the substrate 102.

FIG. 2 illustrates a cross sectional profile view of a package 200 that includes an integrated device and a substrate that may include a stack of interconnects. The package 200 is coupled to a board 101 through a plurality of solder interconnects 106. The board 101 includes at least one board dielectric layer 110 and a plurality of board interconnects 111. The board 101 may include a printed circuit board (PCB).

The package 200 may include a substrate 202 and an integrated device 105. The substrate 202 may be a coreless substrate. The substrate 202 may include at least one dielectric layer 120, at least one dielectric layer 122, a plurality of interconnects 121, a plurality of interconnects 123, a solder resist layer 124 and a solder resist layer 126. The plurality of interconnects 121 may be coupled to the plurality of interconnects 123. The at least one dielectric layer 120 may be coupled to the at least one dielectric layer 122. In some implementations, the at least one dielectric layer 120 and the at least one dielectric layer 122 may be part of the same dielectric layer. The solder resist layer 126 may be coupled to the at least one dielectric layer 120. The solder resist layer 126 may be coupled to the at least one dielectric layer 122. The at least one dielectric layer 120 may be laterally surrounded by the at least one dielectric layer 122. In some implementations, interconnects from the plurality of interconnects 123 may be located laterally to the plurality of a stack of interconnects 125. In some implementations, a via interconnect from the plurality of interconnects 123 may be located laterally to the stack of interconnects 125a. In one example, a via interconnect 123aa from the plurality of interconnects 123 may be located laterally to the first via interconnect, the at two second via interconnect and/or the third via interconnect of the stack of interconnects 125a. In the example of FIG. 2, the via interconnect 123aa may be coupled to and touch a pad interconnect on the first metal layer (M1) and a pad interconnect on the fourth metal layer (M4). In some implementations, a via interconnect from the plurality of interconnects 123 may be coupled to and touch a pad interconnect on the first metal layer (M1) and a pad interconnect on the third metal layer (M3).

The plurality of interconnects 121 may include a plurality of a stack of interconnects 125. The plurality of a stack of interconnects 125 may include a stack of interconnects 125a. The stack of interconnects 125a may include a first pad interconnect, a first via interconnect coupled to the first pad interconnect, a second pad interconnect coupled to the first via interconnect, at least one second via interconnect coupled to the second pad interconnect, a third pad interconnect coupled to the at least one second via interconnect, a third via interconnect coupled to the third pad interconnect. The first via interconnect may be horizontally offset to the at least one second via interconnect. The at least one second via interconnect may include two or more second via interconnects that are horizontally offset to the first via interconnect. The stack of interconnects 125a may also include a fourth pad interconnect coupled to the third via interconnect. The third via interconnect may be horizontally offset to the at least one second via interconnect. The at least one second via interconnect may include two or more second via interconnects that are horizontally offset to the third via interconnect. Different implementations may have different horizontal offset between via interconnects between different metal layers.

The integrated device 105 is coupled to the substrate 202 through a plurality of pillar interconnects 152 and/or a plurality of solder interconnects 150. The plurality of pillar interconnects 152 and/or the plurality of solder interconnects 150 may be coupled to the plurality of a stack of interconnects 125. The plurality of pillar interconnects 152 and/or the plurality of solder interconnects 150 may be coupled and touch to landing pad interconnects of the plurality of a stack of interconnects 125. In some implementations, one or more stack of interconnects from the plurality of a stack of interconnects 125 is configured to provide an electrical path for power and/or ground.

It is also noted that the plurality of a stack of interconnects 125 may be stacks of interconnects that have identical, similar or different configurations and/or designs. Thus, in some implementations, all of the stack of interconnects from the from plurality of a stack of interconnects 125 may have a same configuration. In some implementations, a first set of stack of interconnects from the plurality of a stack of interconnects 125 may have a first configuration, and a second set of stack of interconnects from the plurality of a stack of interconnects 125 may have a second configuration. A different configuration of a stack of interconnects may mean, but not limited to, a different number of via interconnects, a different size in the via interconnect(s), a different size of the pad interconnect(s), a different height in the via interconnect(s) and/or a different horizontal offset between via interconnects. In one example, a stack of interconnects may have two second via interconnects, while another stack of interconnects may have three second via interconnects, while yet another stack of interconnects may have four second via interconnects.

The stack of interconnects 125a may be formed over different number of metal layers, and is not limited to the number of metal layers shown in the disclosure. Moreover, it is noted that different implementations may have different numbers of metal layers of the substrate (e.g., 102, 202).

FIG. 3 illustrates an example of a stack of interconnects 300. The stack of interconnects 300 may represent the stack of interconnects 125a. The stack of interconnects 300 may be an interconnect structure. The stack of interconnects 300 may include a first pad interconnect 301, a first via interconnect 302, a second pad interconnect 303, at least one second via interconnect 304, a third pad interconnect 305, a third via interconnect 306 and a fourth pad interconnect 307. The at least one second via interconnect 304 may include two or more second via interconnects. The at least one second via interconnect 304 may include a second via interconnect 304a, a second via interconnect 304b, a second via interconnect 304c and a second via interconnect 304d. The first pad interconnect 301 may be a landing pad interconnect.

In some implementations, the first pad interconnect 301 may be located on a first metal layer (e.g., M1) of a substrate, the second pad interconnect 303 may be located on a second metal layer (e.g., M2) of a substrate, the third pad interconnect 305 may be located on a third metal layer (e.g., M3) of a substrate, and the fourth pad interconnect 307 may be located on a fourth metal layer (e.g., M4) of a substrate. The first via interconnect 302 may be located between the first pad interconnect 301 and the second pad interconnect 303. The first via interconnect 302 may be coupled to and touch the first pad interconnect 301 and the second pad interconnect 303. The second pad interconnect 303 may have a width and/or a diameter that is greater than the width and/or the diameter of the first pad interconnect 301. The at least one second via interconnect 304 is located between the second pad interconnect 303 and the third pad interconnect 305. The at least one second via interconnect 304 is coupled to and touch the second pad interconnect 303 and the third pad interconnect 305. The third via interconnect 306 is located between the third pad interconnect 305 and the fourth pad interconnect 307. The third via interconnect 306 is coupled to and touch the third pad interconnect 305 and the fourth pad interconnect 307. The third pad interconnect 305 may have a width and/or a diameter that is greater than the width and/or the diameter of the fourth pad interconnect 307.

The at least one second via interconnect 304 may be horizontally offset to the first via interconnect 302 and/or the third via interconnect 306. For example, the second via interconnect 304a may be horizontally offset to the first via interconnect 302 and/or the third via interconnect 306. The second via interconnect 304b may be horizontally offset to the first via interconnect 302 and/or the third via interconnect 306. The second via interconnect 304c may be horizontally offset to the first via interconnect 302 and/or the third via interconnect 306. The second via interconnect 304d may be horizontally offset to the first via interconnect 302 and/or the third via interconnect 306. A via interconnect that is horizontally offset to another via interconnect may mean that a center vertical line of the via interconnect may be horizontally offset to a center vertical line of the another via interconnect.

As mentioned above, different implementations may have different horizontal offsets between via interconnects located between different metal layers. In some implementations, a first via interconnect may be horizontally offset to another via interconnect by at least half the width of the first via interconnect and/or by at least half the width of the second via interconnect. For example, in some implementations, the horizontal offset between the center vertical line of the via interconnect 302 and the center vertical line of the via interconnect 304a may be at least half the width of the via interconnect 302 and/or at least one half the width of the via interconnect 304a.

### Exemplary Package Comprising an Integrated Device and a Substrate With Stacks of Interconnects

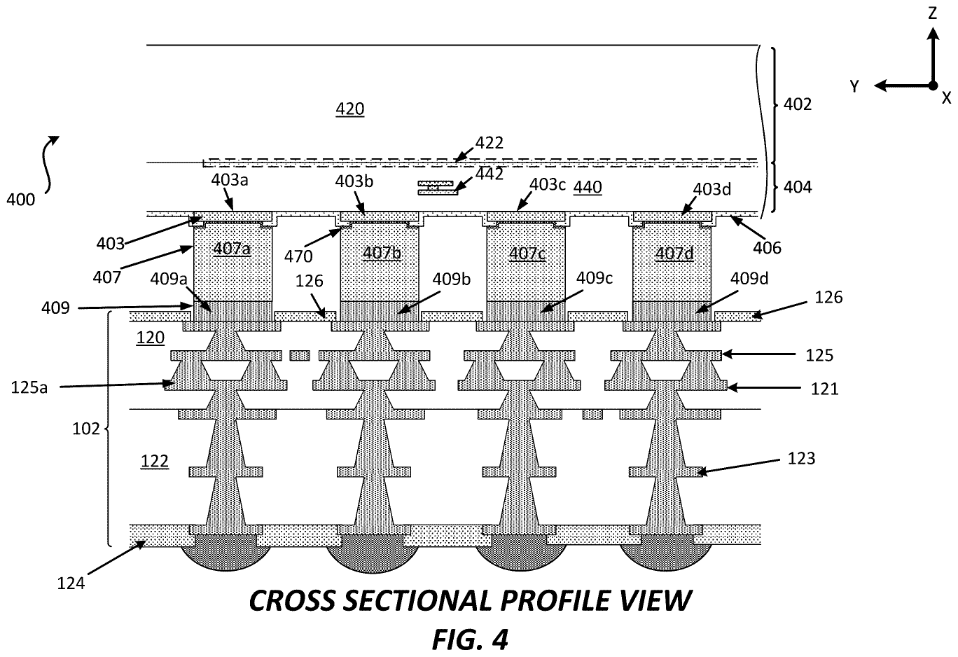

FIG. 4 illustrates a cross sectional profile view of an integrated device 400 that is coupled to the substrate 102. The integrated device 400 includes a die substrate portion 402, and a die interconnection portion 404. The die substrate portion 242 includes a die substrate 420 and an active region 422. The active region 422 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 422 of the die substrate 420. The die substrate 420 may include silicon (Si).

The die interconnection portion 404 includes at least one dielectric layer 440 and a plurality of die interconnects 442. The die interconnection portion 404 is coupled to the die substrate portion 402. The plurality of die interconnects 442 are coupled to the active region 422 of the die substrate portion 402. In some implementations, a back end of line (BEOL) process may be used to fabricate the die interconnection portion 404.

The integrated device 400 includes a plurality of pad interconnects 403 and a passivation layer 406. The plurality of pad interconnects 403 and/or the passivation layer 406 may be coupled to the die interconnection portion 404. The plurality of pad interconnects 403 are coupled to the plurality of die interconnects 442. In some implementations, the plurality of pad interconnects 403 and/or the passivation layer 406 may be considered part of the die interconnection portion 404. The plurality of pad interconnects 403 include a pad interconnect 403a, a pad interconnect 403b, a pad interconnect 403c and a pad interconnect 403d.

The integrated device 400 includes a plurality of pillar interconnects 407, a plurality of solder interconnects 409. The plurality of pillar interconnects 407 include a pillar interconnect 407a, a pillar interconnect 407b, a pillar interconnect 407c and a pillar interconnect 407d. The plurality of solder interconnects 409 include a solder interconnect 409a, a solder interconnect 409b, a solder interconnect 409c and a solder interconnect 409d. The plurality of pillar interconnects 407 may be coupled to and touch the plurality of pad interconnects 403. Some of solder interconnects from the plurality of interconnects 409 may be coupled to and touch the plurality of pillar interconnects 407. The plurality of pillar interconnects 407 may include a seed layer 470. The seed layer 470 may be an under bump metallization interconnect. In some implementations, the under bump metallization interconnect may be considered part of the plurality of pillar interconnects 407. The seed layer 470 may be an under bump metallization interconnect.

The integrated device 400 is coupled to the substrate 102 through a plurality of pillar interconnects 407 and a plurality of solder interconnects 409. The integrated device 400 may be coupled to the plurality of a stack of interconnects 125 of the substrate 102 through a plurality of pillar interconnects 407 and a plurality of solder interconnects 409. For example, the pillar interconnect 407a may be coupled to the stack of interconnects 125a through the solder interconnect 409a. The pillar interconnect 407a may or may not touch the stack of interconnects 125a. The pillar interconnect 407a may be coupled to a landing pad interconnect (e.g., 301) of the stack of interconnects 125a. The pillar interconnect 407a may vertically overlap with the stack of interconnects 125a. In some implementations, the pillar interconnect 407a may align with one or more via interconnects of the stack of interconnects 125a and may horizontally offset with one or more other via interconnects of the stack of interconnects 125a.

An integrated device (e.g., 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 105) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G, 6G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Substrate Comprising Stacks of Interconnects

In some implementations, fabricating a substrate includes several processes. FIGS. 5A-5H illustrate an exemplary sequence for providing or fabricating a substrate. In some implementations, the sequence of FIGS. 5A-5H may be used to provide or fabricate a laminated substrate. The substrate that is fabricated in FIGS. 5A-5H may replace the substrate 102 and/or the substrate 202 of the disclosure.

It should be noted that the sequence of FIGS. 5A-5H may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 5A, illustrates a state after a carrier 501 is provided. The carrier 501 may include a core layer. The core layer may include seed layers on surfaces of the core layer.

Stage 2 illustrates a state after a plurality of interconnects 502 and a plurality of interconnects 504 are formed. The plurality of interconnects 502 may be coupled to a first surface (e.g., top surface) of the carrier 501. The plurality of interconnects 504 may be coupled to a second surface (e.g., bottom surface) of the carrier 501. A plating process and/or an etching process may be used to form the plurality of interconnects 502 and the plurality of interconnects 504. The plurality of interconnects 502 may be formed on a first seed layer of the carrier 501. The plurality of interconnects 504 may be formed on a second seed layer of the carrier 501. The plurality of interconnects 502 may include a plurality of landing pad interconnects. The plurality of interconnects 504 may include a plurality of landing pad interconnects.

Stage 3 illustrates a state after a dielectric layer 510 and a dielectric layer 520 are provided. The dielectric layer 510 may be coupled to the first surface of the carrier 501. The dielectric layer 520 may be coupled to the second surface of the carrier 501. A deposition and/or a lamination process may be used to form the dielectric layer 510 and/or the dielectric layer 520. The dielectric layer 510 and/or the dielectric layer 520 may include prepreg, polymer and/or Ajinomoto Build-up Film (ABF).

Stage 4 of FIG. 5B, illustrates a state after a plurality of cavities 511 are formed in the dielectric layer 510, and a plurality of cavities 521 are formed in the dielectric layer 520. An exposure and development process may be used to form the plurality of cavities 511 in the dielectric layer 510 and the plurality of cavities 521 in the dielectric layer 520. Different implementations may use different processes to form the plurality of cavities. The plurality of cavities 511 and/or the plurality of cavities 521 may be openings in dielectric layer(s).

Stage 5 illustrates a state after a plurality of interconnects 512 are formed in the dielectric layer 510, and a plurality of interconnects 524 are formed in the dielectric layer 520. The plurality of interconnects 512 may be coupled to the plurality of interconnects 502. The plurality of interconnects 524 may be coupled to the plurality of interconnects 504. A plating process and/or an etching process may be used to form the plurality of interconnects 512 and/or the plurality of interconnects 524.

Stage 6, as shown in FIG. 5C, illustrates a state after a dielectric layer 530 and a dielectric layer 540 are provided. The dielectric layer 530 may be coupled to the dielectric layer 510. The dielectric layer 540 may be coupled to the dielectric layer 520. A deposition and/or a lamination process may be used to form the dielectric layer 530 and/or the dielectric layer 540. The dielectric layer 530 and/or the dielectric layer 540 may include prepreg, polymer and/or Ajinomoto Build-up Film (ABF).

Stage 7 illustrates a state after a plurality of cavities 531 are formed in the dielectric layer 530, and a plurality of cavities 541 are formed in the dielectric layer 540. An exposure and development process may be used to form the plurality of cavities 531 in the dielectric layer 530 and the plurality of cavities 541 in the dielectric layer 540. Different implementations may use different processes to form the plurality of cavities. The plurality of cavities 531 and/or the plurality of cavities 541 may be openings in dielectric layer(s).

Stage 8, as shown in FIG. 5D, illustrates a state after a plurality of interconnects 532 are formed in the dielectric layer 530, and a plurality of interconnects 544 are formed in the dielectric layer 540. The plurality of interconnects 532 may be coupled to the plurality of interconnects 512. The plurality of interconnects 544 may be coupled to the plurality of interconnects 524. A plating process and/or an etching process may be used to form the plurality of interconnects 532 and/or the plurality of interconnects 544.

Stage 9 illustrates a state after a dielectric layer 550 and a dielectric layer 560 are provided. The dielectric layer 550 may be coupled to the dielectric layer 530. The dielectric layer 560 may be coupled to the dielectric layer 540. A deposition and/or a lamination process may be used to form the dielectric layer 550 and/or the dielectric layer 560. The dielectric layer 550 and/or the dielectric layer 560 may include prepreg, polymer and/or Ajinomoto Build-up Film (ABF).

Stage 10, as shown in FIG. 5E, illustrates a state after a plurality of cavities 551 are formed in the dielectric layer 550, and a plurality of cavities 561 are formed in the dielectric layer 560. An exposure and development process may be used to form the plurality of cavities 551 in the dielectric layer 550 and the plurality of cavities 561 in the dielectric layer 560. Different implementations may use different processes to form the plurality of cavities. The plurality of cavities 551 and/or the plurality of cavities 561 may be openings in dielectric layer(s).

Stage 11 illustrates a state after a plurality of interconnects 552 are formed in the dielectric layer 550, and a plurality of interconnects 564 are formed in the dielectric layer 560. The plurality of interconnects 552 may be coupled to the plurality of interconnects 532. The plurality of interconnects 564 may be coupled to the plurality of interconnects 544. A plating process and/or an etching process may be used to form the plurality of interconnects 552 and/or the plurality of interconnects 564. The dielectric layer 570 may represent the dielectric layer 510, the dielectric layer 530 and/or the dielectric layer 550. The dielectric layer 580 may represent the dielectric layer 520, the dielectric layer 540 and/or the dielectric layer 560.

Stage 12, as shown in FIG. 5F, illustrates a state after additional build up layers are formed. For example, stage 12 illustrates a state after additional dielectric layers and additional interconnects are formed. For example, a dielectric layer 122a may be formed and coupled to the dielectric layer 570. A dielectric layer 122b may be formed and coupled to the dielectric layer 580. A lamination process and/or a deposition process may be used to form the dielectric layer 122a and the dielectric layer 122b.

Stage 12 may further illustrate a plurality of interconnects 123a that are formed and coupled to the plurality of interconnects 572. The plurality of interconnects 572 may be formed in the dielectric layer 122a. The plurality of interconnects 572 may represent the plurality of interconnects 502, the plurality of interconnects 512, the plurality of interconnects 532 and/or the plurality of interconnects 552. The plurality of interconnects 572 may include stacks of interconnects, such as the plurality of a stack of interconnects 125. The plurality of interconnects 572 may be fabricated in a similar manner as described for the plurality of interconnects 502, the plurality of interconnects 512, the plurality of interconnects 532 and/or the plurality of interconnects 552. The plurality of interconnects 572 may include via interconnects that have a height that is greater than the height of via interconnects from the plurality of interconnects 502, the plurality of interconnects 512, the plurality of interconnects 532 and/or the plurality of interconnects 552.

Stage 12 may further illustrate a plurality of interconnects 123b that are formed and coupled to the plurality of interconnects 584. The plurality of interconnects 584 may be formed in the dielectric layer 122a. The plurality of interconnects 584 may represent the plurality of interconnects 504, the plurality of interconnects 524, the plurality of interconnects 544 and/or the plurality of interconnects 564. The plurality of interconnects 584 may include stacks of interconnects, such as the plurality of a stack of interconnects 125. The plurality of interconnects 584 may be fabricated in a similar manner as described for the plurality of interconnects 504, the plurality of interconnects 524, the plurality of interconnects 544 and/or the plurality of interconnects 564. The plurality of interconnects 584 may include via interconnects that have a height that is greater than the height of via interconnects from the plurality of interconnects 504, the plurality of interconnects 524, the plurality of interconnects 544 and/or the plurality of interconnects 564.

In some implementations, a plurality of interconnects 123a may be formed laterally to the plurality of interconnects 572 and/or a plurality of interconnects 123b may be formed laterally to the plurality of interconnects 584, which may result in the interconnects to have a similar configuration as the substrate 202 of FIG. 2.

Stage 13, as shown in FIG. 5G, illustrates a state after separation of the dielectric layers from the carrier 501. For example, the dielectric layer 570 and the dielectric layer 122a are separated from the carrier 501 to form a substrate 505 (e.g., coreless substrate). In another example, the dielectric layer 580 and the dielectric layer 122b are separated from the carrier 501 to form a substrate 506 (e.g., coreless substrate). The substrate 605 and/or the substrate 606 may be used instead of the substrate 102 and/or the substrate 202.

Stage 14, as shown in FIG. 5H, illustrates a state after a solder resist layer 124 and a solder resist layer 126 are formed on the substrate 102. A deposition process and/or a lamination process may be used to form the solder resist layer 124 and/or the solder resist layer 126.

### Exemplary Flow Diagram of a Method for Fabricating a Substrate Comprising Stacks of Interconnects

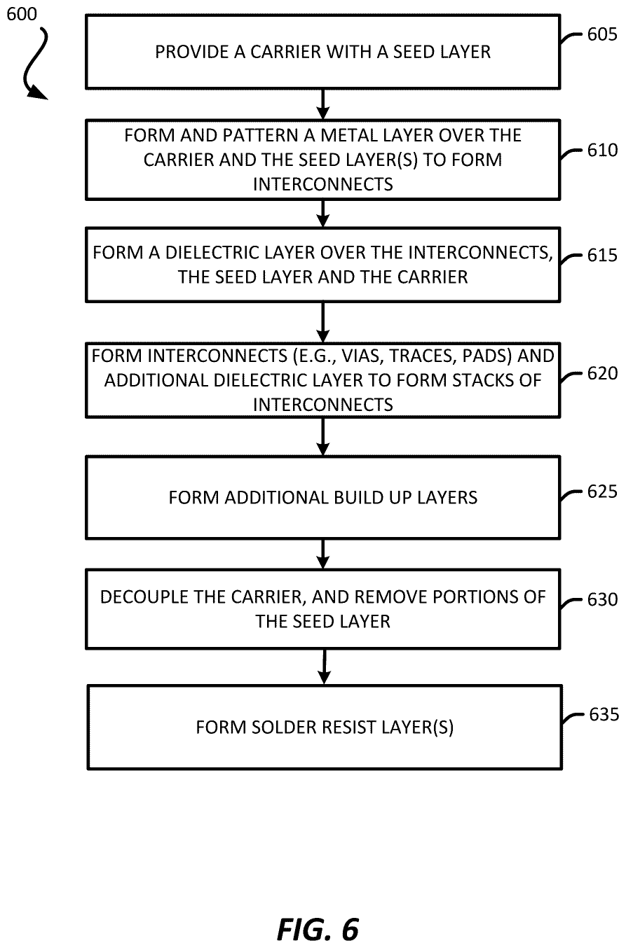

In some implementations, fabricating a substrate includes several processes. FIG. 6 illustrates an exemplary flow diagram of a method 600 for providing or fabricating a substrate. In some implementations, the method 600 of FIG. 6 may be used to provide or fabricate a substrate.

It should be noted that the method 600 of FIG. 6 may combine one or more processes in order to simplify and/or clarify the method for providing or fabricating a substrate. In some implementations, the order of the processes may be changed or modified.

The method provides (at 605) a carrier. The carrier may include seed layers. Stage 1 of FIG. 5A, illustrates and describes an example of a state after a carrier 501 is provided. The carrier 501 may include a core layer. The core layer may include seed layers on surfaces of the core layer.

The method forms (at 610) interconnects. Stage 2 of FIG. 5A, illustrates a state after a plurality of interconnects 502 and a plurality of interconnects 504 are formed. The plurality of interconnects 502 may be coupled to a first surface (e.g., top surface) of the carrier 501. The plurality of interconnects 504 may be coupled to a second surface (e.g., bottom surface) of the carrier 501. A plating process and/or an etching process may be used to form the plurality of interconnects 502 and the plurality of interconnects 504. The plurality of interconnects 502 may be formed on a first seed layer of the carrier 501. The plurality of interconnects 504 may be formed on a second seed layer of the carrier 501. The plurality of interconnects 502 may include a plurality of landing pad interconnects. The plurality of interconnects 504 may include a plurality of landing pad interconnects.

The method forms (at 615) a dielectric layer. Stage 3 of FIG. 5A, illustrates and describes an example of a state after a dielectric layer 510 and a dielectric layer 520 are provided. The dielectric layer 510 may be coupled to the first surface of the carrier 501. The dielectric layer 520 may be coupled to the second surface of the carrier 501. A deposition and/or a lamination process may be used to form the dielectric layer 510 and/or the dielectric layer 520. The dielectric layer 510 and/or the dielectric layer 520 may include prepreg, polymer and/or Ajinomoto Build-up Film (ABF).

Forming the dielectric layer may include forming cavities in the dielectric layer. Stage 4 of FIG. 5B, illustrates and describes an example of a state after a plurality of cavities 511 are formed in the dielectric layer 510, and a plurality of cavities 521 are formed in the dielectric layer 520. An exposure and development process may be used to form the plurality of cavities 511 in the dielectric layer 510 and the plurality of cavities 521 in the dielectric layer 520. Different implementations may use different processes to form the plurality of cavities. The plurality of cavities 511 and/or the plurality of cavities 521 may be openings in dielectric layer(s).

The method forms (at 620) interconnects and dielectric layers to form stacks of interconnects. Stage 5 of FIG. 5B, illustrates and describes an example of a state after a plurality of interconnects 512 are formed in the dielectric layer 510, and a plurality of interconnects 524 are formed in the dielectric layer 520. The plurality of interconnects 512 may be coupled to the plurality of interconnects 502. The plurality of interconnects 524 may be coupled to the plurality of interconnects 504. A plating process and/or an etching process may be used to form the plurality of interconnects 512 and/or the plurality of interconnects 524.

Stage 6 of FIG. 5C, illustrates and describes an example of a state after a dielectric layer 530 and a dielectric layer 540 are provided. The dielectric layer 530 may be coupled to the dielectric layer 510. The dielectric layer 540 may be coupled to the dielectric layer 520. A deposition and/or a lamination process may be used to form the dielectric layer 530 and/or the dielectric layer 540. The dielectric layer 530 and/or the dielectric layer 540 may include prepreg, polymer and/or Ajinomoto Build-up Film (ABF).

Stage 7 of FIG. 5C, illustrates and describes an example of a state after a plurality of cavities 531 are formed in the dielectric layer 530, and a plurality of cavities 541 are formed in the dielectric layer 540. An exposure and development process may be used to form the plurality of cavities 531 in the dielectric layer 530 and the plurality of cavities 541 in the dielectric layer 540. Different implementations may use different processes to form the plurality of cavities. The plurality of cavities 531 and/or the plurality of cavities 541 may be openings in dielectric layer(s).

Stage 8 of FIG. 5D, illustrates and describes an example of a state after a plurality of interconnects 532 are formed in the dielectric layer 530, and a plurality of interconnects 544 are formed in the dielectric layer 540. The plurality of interconnects 532 may be coupled to the plurality of interconnects 512. The plurality of interconnects 544 may be coupled to the plurality of interconnects 524. A plating process and/or an etching process may be used to form the plurality of interconnects 532 and/or the plurality of interconnects 544.

Stage 9 of FIG. 5D, illustrates and describes an example of a state after a dielectric layer 550 and a dielectric layer 560 are provided. The dielectric layer 550 may be coupled to the dielectric layer 530. The dielectric layer 560 may be coupled to the dielectric layer 540. A deposition and/or a lamination process may be used to form the dielectric layer 550 and/or the dielectric layer 560. The dielectric layer 550 and/or the dielectric layer 560 may include prepreg, polymer and/or Ajinomoto Build-up Film (ABF).

Stage 10 of FIG. 5E, illustrates and describes an example of a state after a plurality of cavities 551 are formed in the dielectric layer 550, and a plurality of cavities 561 are formed in the dielectric layer 560. An exposure and development process may be used to form the plurality of cavities 551 in the dielectric layer 550 and the plurality of cavities 561 in the dielectric layer 560. Different implementations may use different processes to form the plurality of cavities. The plurality of cavities 551 and/or the plurality of cavities 561 may be openings in dielectric layer(s).

Stage 11 of FIG. 5E, illustrates and describes an example of a state after a plurality of interconnects 552 are formed in the dielectric layer 550, and a plurality of interconnects 564 are formed in the dielectric layer 560. The plurality of interconnects 552 may be coupled to the plurality of interconnects 532. The plurality of interconnects 564 may be coupled to the plurality of interconnects 544. A plating process and/or an etching process may be used to form the plurality of interconnects 552 and/or the plurality of interconnects 564. The dielectric layer 570 may represent the dielectric layer 510, the dielectric layer 530 and/or the dielectric layer 550. The dielectric layer 580 may represent the dielectric layer 520, the dielectric layer 540 and/or the dielectric layer 560.

The method forms (at 625) additional interconnects and dielectric layer(s). Stage 12 of FIG. 5F, illustrates and describes an example of a state after additional build up layers are formed. For example, stage 12 illustrates a state after additional dielectric layers and additional interconnects are formed. For example, a dielectric layer 122a may be formed and coupled to the dielectric layer 570. A dielectric layer 122b may be formed and coupled to the dielectric layer 580. A lamination process and/or a deposition process may be used to form the dielectric layer 122a and the dielectric layer 122b.

Stage 12 of FIG. 5F, may further illustrate and describe an example of a plurality of interconnects 123a that are formed and coupled to the plurality of interconnects 572. The plurality of interconnects 572 may be formed in the dielectric layer 122a. The plurality of interconnects 572 may represent the plurality of interconnects 502, the plurality of interconnects 512, the plurality of interconnects 532 and/or the plurality of interconnects 552. The plurality of interconnects 572 may include stacks of interconnects, such as the plurality of a stack of interconnects 125. The plurality of interconnects 572 may be fabricated in a similar manner as described for the plurality of interconnects 502, the plurality of interconnects 512, the plurality of interconnects 532 and/or the plurality of interconnects 552. The plurality of interconnects 572 may include via interconnects that have a height that is greater than the height of via interconnects from the plurality of interconnects 502, the plurality of interconnects 512, the plurality of interconnects 532 and/or the plurality of interconnects 552.

Stage 12 may further illustrate and describe an example of a plurality of interconnects 123b that are formed and coupled to the plurality of interconnects 584. The plurality of interconnects 584 may be formed in the dielectric layer 122a. The plurality of interconnects 584 may represent the plurality of interconnects 504, the plurality of interconnects 524, the plurality of interconnects 544 and/or the plurality of interconnects 564. The plurality of interconnects 584 may include stacks of interconnects, such as the plurality of a stack of interconnects 125. The plurality of interconnects 584 may be fabricated in a similar manner as described for the plurality of interconnects 504, the plurality of interconnects 524, the plurality of interconnects 544 and/or the plurality of interconnects 564. The plurality of interconnects 584 may include via interconnects that have a height that is greater than the height of via interconnects from the plurality of interconnects 504, the plurality of interconnects 524, the plurality of interconnects 544 and/or the plurality of interconnects 564.

In some implementations, a plurality of interconnects 123a may be formed laterally to the plurality of interconnects 572 and/or a plurality of interconnects 123b may be formed laterally to the plurality of interconnects 584, which may result in the interconnects to have a similar configuration as the substrate 202 of FIG. 2.

The method decouples (at 630) the dielectric layers from the carrier. Stage 13 of FIG. 5G, illustrates and describes an example of a state after separation of the dielectric layers from the carrier 501. For example, the dielectric layer 570 and the dielectric layer 122a are separated from the carrier 501 to form a substrate 505 (e.g., coreless substrate). In another example, the dielectric layer 580 and the dielectric layer 122b are separated from the carrier 501 to form a substrate 506 (e.g., coreless substrate). The substrate 605 and/or the substrate 606 may be used instead of the substrate 102 and/or the substrate 202.

The method forms (at 635) solder resist layer(s) on the substrate. In some implementations, once separation occurs, one or more solder resist layers may be formed on surface(s) of the substrate 605 and/or the substrate 606. Stage 14, as shown in FIG. 5H, illustrates and describes an example of a state after a solder resist layer 124 and a solder resist layer 126 are formed on the substrate 102. A deposition process and/or a lamination process may be used to form the solder resist layer 124 and/or the solder resist layer 126.

### Exemplary Electronic Devices

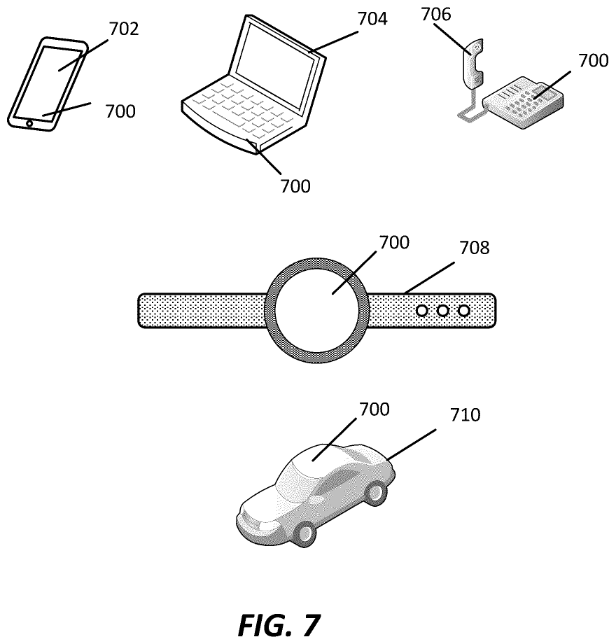

FIG. 7 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 702, a laptop computer device 704, a fixed location terminal device 706, a wearable device 708, or automotive vehicle 710 may include a device 700 as described herein. The device 700 may be, for example, any of the devices and/or integrated circuit (IC) packages described herein. The devices 702, 704, 706 and 708 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5H and 6-7 may be rearranged and/or combined into a single component, process, feature or function or embodied in several components, processes, or functions. Additional elements, components, processes, and/or functions may also be added without departing from the disclosure. It should also be noted FIGS. 1-4, 5A-5H and 6-7 and its corresponding description in the present disclosure is not limited to dies and/or ICs. In some implementations, FIGS. 1-4, 5A-5H and 6-7 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate comprising at least one dielectric layer; and a plurality of interconnects comprising a stack of interconnects that include a first pad interconnect; a first via interconnect coupled to the first pad interconnect; a second pad interconnect coupled to the first via interconnect; at least two second via interconnects coupled to the second pad interconnect; and a third pad interconnect coupled to the at least two second via interconnect; and an integrated device coupled to the stack of interconnects.

Aspect 2: The package of aspect 1, wherein the at least two second via interconnects are horizontally offset to the first via interconnect.

Aspect 3: The package of aspects 1 through 2, wherein the first pad interconnect includes a landing pad interconnect.

Aspect 4: The package of aspects 1 through 3, wherein the at least two second via interconnects are located between the second pad interconnect and the third pad interconnect.

Aspect 5: The package of aspect 4, wherein the first via interconnect is located between the first pad interconnect and the second pad interconnect.

Aspect 6: The package of aspects 1 through 5, wherein the at least two second via interconnects include three of more second via interconnects located between the second pad interconnect and the third pad interconnect.

Aspect 7: The package of aspect 6, wherein the three or more second via interconnects are each horizontally offset to the first via interconnect.

Aspect 8: The package of aspects 1 through 7, wherein the stack of interconnects further includes a third via interconnect coupled to the third pad interconnect; and a fourth pad interconnect coupled to the third via interconnect.

Aspect 9: The package of aspects 1 through 8, wherein the integrated device is coupled to a plurality of stack of interconnects through a plurality of pillar interconnects and a plurality of solder interconnects.

Aspect 10: The package of aspect 9, wherein the integrated device is coupled to the first pad interconnect of the stack of interconnects, through a pillar interconnect and a solder interconnect.

Aspect 11: A package comprising a substrate comprising at least one dielectric layer; and a plurality of interconnects comprising a plurality of a stack of interconnects comprising a first plurality of via interconnects, wherein vias interconnects from the first plurality of via interconnects comprise a first height; and a second plurality of via interconnects, wherein via interconnects from the second plurality of via interconnects comprise a second height that is different from the first height; and an integrated device coupled to the plurality of a stack of interconnects.

Aspect 12: The package of aspect 11, wherein at least some via interconnects from the first plurality of via interconnects are located between a first metal layer and a second layer, and wherein at least some via interconnects from the second plurality of via interconnects are located between a third metal layer and a fourth metal layer.

Aspect 13: The package of aspect 12, wherein at least some via interconnects from the first plurality of via interconnects are located between a second metal layer and a third layer.

Aspect 14: The package of aspects 11 through 13, wherein the substrate comprises a first metal layer, a second metal layer, a third metal layer, a fourth metal layer and a fifth metal layer, wherein at least some via interconnects from the first plurality of via interconnects are located between the first metal layer and the second layer, and wherein at least some via interconnects from the second plurality of via interconnects are located between the fourth metal layer and the fifth metal layer.

Aspect 15: The package of aspect 14, wherein at least some via interconnects from the first plurality of via interconnects are located between the second metal layer and the third metal layer.

Aspect 16: The package of aspect 15, wherein at least some via interconnects from the first plurality of via interconnects are located between the third metal layer and the fourth metal layer.

Aspect 17: The package of aspects 15 through 16, wherein at least some via interconnects from the second plurality of via interconnects are located between the first metal layer and the fourth metal layer.

Aspect 18: The package of aspects 11 through 17, wherein the first plurality of a stack of interconnects comprise an interconnect structure comprising a first pad interconnect on a first metal layer; a first via interconnect coupled to the first pad interconnect; a second pad interconnect on a second metal layer; a plurality of via interconnects coupled to the second pad interconnect, wherein the plurality of via interconnects comprises a second via interconnect and a third via interconnect; a third pad interconnect on a third metal layer, wherein the third pad interconnect is coupled to the plurality of via interconnects, and a fourth via interconnect coupled to the third pad interconnect.

Aspect 19: The package of aspect 18, wherein the plurality of via interconnects are horizontally offset to the first via interconnect and the fourth via interconnect.

Aspect 20: The package of aspect 19, wherein the plurality of via interconnects are located between the second pad interconnect and the third pad interconnect.

Aspect 21: The package of aspects 1 through 20, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising:
at least one dielectric layer; and
a plurality of interconnects comprising a stack of interconnects that includes:
a first pad interconnect;
a first via interconnect coupled to the first pad interconnect;
a second pad interconnect coupled to the first via interconnect;
at least two second via interconnects coupled to the second pad interconnect; and
a third pad interconnect coupled to the at least two second via interconnect; and
an integrated device coupled to the stack of interconnects.

2. The package of claim 1, wherein the at least two second via interconnects are horizontally offset to the first via interconnect.

3. The package of claim 1, wherein the first pad interconnect includes a landing pad interconnect.

4. The package of claim 1, wherein the at least two second via interconnects are located between the second pad interconnect and the third pad interconnect.

5. The package of claim 4, wherein the first via interconnect is located between the first pad interconnect and the second pad interconnect.

6. The package of claim 1, wherein the at least two second via interconnects include three of more second via interconnects located between the second pad interconnect and the third pad interconnect.

7. The package of claim 6, wherein the three or more second via interconnects are each horizontally offset to the first via interconnect.

8. The package of claim 1, wherein the stack of interconnects further includes:
a third via interconnect coupled to the third pad interconnect; and
a fourth pad interconnect coupled to the third via interconnect.

9. The package of claim 1, wherein the integrated device is coupled to a plurality of stacks of interconnects through a plurality of pillar interconnects and a plurality of solder interconnects.

10. The package of claim 9, wherein the integrated device is coupled to the first pad interconnect of the stack of interconnects, through a pillar interconnect and a solder interconnect.

11. A package comprising:
a substrate comprising:
at least one dielectric layer; and
a plurality of interconnects comprising:
a plurality of a stack of interconnects comprising a first plurality of via interconnects, wherein vias interconnects from the first plurality of via interconnects comprise a first height; and
a second plurality of via interconnects, wherein via interconnects from the second plurality of via interconnects comprise a second height that is different from the first height; and
an integrated device coupled to the plurality of a stack of interconnects.

12. The package of claim 11,
wherein at least some via interconnects from the first plurality of via interconnects are located between a first metal layer and a second layer, and
wherein at least some via interconnects from the second plurality of via interconnects are located between a third metal layer and a fourth metal layer.

13. The package of claim 12, wherein at least some via interconnects from the first plurality of via interconnects are located between a second metal layer and a third layer.

14. The package of claim 11,
wherein the substrate comprises a first metal layer, a second metal layer, a third metal layer, a fourth metal layer and a fifth metal layer,
wherein at least some via interconnects from the first plurality of via interconnects are located between the first metal layer and the second layer, and
wherein at least some via interconnects from the second plurality of via interconnects are located between the fourth metal layer and the fifth metal layer.

15. The package of claim 14, wherein at least some via interconnects from the first plurality of via interconnects are located between the second metal layer and the third metal layer.

16. The package of claim 15, wherein at least some via interconnects from the first plurality of via interconnects are located between the third metal layer and the fourth metal layer.

17. The package of claim 15, wherein at least some via interconnects from the second plurality of via interconnects are located between the first metal layer and the fourth metal layer.

18. The package of claim 11, wherein the plurality of a stack of interconnects comprise an interconnect structure comprising:
a first pad interconnect on a first metal layer;
a first via interconnect coupled to the first pad interconnect;
a second pad interconnect on a second metal layer;
a plurality of via interconnects coupled to the second pad interconnect, wherein the plurality of via interconnects comprises a second via interconnect and a third via interconnect;
a third pad interconnect on a third metal layer, wherein the third pad interconnect is coupled to the plurality of via interconnects, and
a fourth via interconnect coupled to the third pad interconnect.

19. The package of claim 18, wherein the plurality of via interconnects are horizontally offset to the first via interconnect and the fourth via interconnect.

20. The package of claim 19, wherein the plurality of via interconnects are located between the second pad interconnect and the third pad interconnect.
